(19) United States
(12) Patent Application Publication
(10) Pub. No.: US 2025/0112155 A1
(43) Pub. Date: Apr. 3, 2025

(54) CONFORMAL COATINGS WITH SPATIALLY DEFINED SURFACE ENERGIES FOR DIE-TO-WAFER SELF-ALIGNMENT ASSISTED ASSEMBLY

(71) Applicant: Intel Corporation, Santa Clara, CA (US)

(72) Inventors: Kimin Jun, Portland, OR (US); Scott Clendenning; Feras Eid, Chandler, AZ (US); Robert Jordan, Portland, OR (US); Wenhao Li, Chandler, AZ (US); Jiun-Ruey Chen, Hillsboro, OR (US); Tayseer Mahdi, Hillsboro, OR (US); Carlos Felipe Bedoya Arroyave, Portland, OR (US); Shashi Bhushan Sinha, Hillsboro, OR (US); Anandi Roy, Hillsboro, OR (US); Tristan Tronic, Aloha, OR (US); Dominique Adams, Portland, OR (US); William Brezinski, Beaverton, OR (US); Richard Vreeland, Beaverton, OR (US); Thomas Sounart, Chandler, AZ (US); Brian Barley, Beaverton, OR (US); Jeffery Bielefeld, Forest Grove, OR (US)

(73) Assignee: Intel Corporation, Santa Clara, CA (US)

(21) Appl. No.: 18/374,532

(22) Filed: Sep. 28, 2023

(51) Int. Cl. H01L 23/532; H01L 21/48; H01L 23/498; H01L 23/528

(52) U.S. Cl. CPC H01L 23/53214; H01L 21/485; H01L 23/49894; H01L 23/5283

(57) ABSTRACT

Hybrid bonded die stacks, related apparatuses, systems, and methods of fabrication are disclosed. One or both of an integrated circuit (IC) die hybrid bonding region and a base substrate hybrid bonding region are surrounded by a protective layer and hydrophobic structures on the protective layer. The protective layer is formed prior to pre-bond processing to protect the hybrid bonding region during plasma activation, clean test, high temperature processing, or the like. Immediately prior to bonding, the hydrophobic structures are selectively applied to the protective layer. The hybrid bonding regions are brought together with a liquid droplet therebetween, and capillary forces cause the IC die to self-align. A hybrid bond is formed by evaporating the droplet and a subsequent anneal. The hydrophobic structures contain the liquid droplet for alignment during bonding.

### BACKGROUND

The integrated circuit industry is continually striving to produce ever faster, smaller, and more efficient integrated circuit devices, packages, and systems for use in various electronic products. Current die stacks can be formed using solder to solder bump attachment techniques. For example, on two separate dies, solder bumps may be deposited on copper pillars. The solder bumps may then be brought into contact to join the dies, and underfill material may be formed between the solder bonds and copper pillars. Such processes disadvantageously necessitate a large distance between the bonded dies and large bond pitches.

Alternatively, hybrid bonds may be formed between corresponding metallic bond pads on the two dies, with the metallic bond pads interspersed among dielectric material (e.g., an oxide). Prior to bonding, the surface of each die may be controlled to promote bonding by providing a recess of the metallic bond pads relative to the dielectric material, having the dielectric material be planar and relatively smooth, and others. Furthermore, prior to bonding, the hybrid bond regions may be cleaned and activated using plasma processing, the dies may be tested, and so on. The dies, having mirror image bond pads, are then brought together such that corresponding metallic bond pads and corresponding dielectric material surfaces of the two dies interface with one another. At room temperature, the dielectric materials adhere sufficiently to one another (due to Van der Waals forces) to maintain a bond. A high temperature anneal is then performed to bond the corresponding metallic bond pads, and to improve the dielectric material bond. Such processes reduce the distance between the bonded dies, reduce pitches between the metal bonds, and offer other advantages. For example, solder bump techniques may be limited to pitches of about 30 μm while hybrid bonding can attain less than 10 μm and even less than 1 μm pitches.

However, difficulties in forming 3D die stacks using hybrid bonding techniques persist. For example, in contexts where the hybrid bonding regions are surrounded by hydrophobic materials, the discussed pre-bond processing can undesirably remove all or portions of the hydrophobic materials. It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or

FIG. 1 provides a flow diagram illustrating an example process for fabricating IC structures inclusive of 3D die stacks with hybrid bonding regions within a protective layer and hydrophobic structures on the protective layer;

FIGS. 2, 3, 4, 5, 6, 7, 8, 9, 10, 11, 12, 13, and 14A are illustrations of cross-sectional side views of integrated circuit (IC) structures having a hybrid bonding region surrounded by a protective layer and hydrophobic structures being prepared for self-alignment bonding;

FIG. 14B illustrates a top-down view of the IC structure of FIG. 14A showing bonding regions defined by a hydrophobic pattern;

FIGS. 15, 16, 17, and 18 are illustrations of cross-sectional side views of the fabrication of IC structures are illustrations of cross-sectional side views of hybrid bonding of IC dies to a base substrate;

FIG. 19 is an illustration of a cross-sectional side view of an assembly structure similar to the IC structure of FIG. 18 after packaging and deployment of heat removal solutions;

FIG. 20 illustrates an example microelectronic device system 2000 including a 3D die stack having a hybrid bond with a protective layer (PL) and a hydrophobic layer (HL) around an outer perimeter of the hybrid bond; and

FIG. 21 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Integrated circuit structures, 3D die stack structures, devices, apparatuses, systems, and methods are described herein related to hybrid bonding with the hybrid bonding regions surrounded by a protective layer, that is resilient to pre-bonding processing, and hydrophobic structures, applied prior to hybrid bonding, on the protective layer.

As described above, hybrid bonding techniques offer advantages in the assembly of 3D die stacks. As used herein, the term multi-level 3D die stack indicates a stack of devices or structures having at least partially vertically aligned layers such that each layer or level of the 3D die stack may employ one or more IC dies each. The term layer or level of a 3D die stack indicates a horizontal portion of the 3D die stack that includes only one depth of device within the horizontal portion (e.g., each layer or level may have any number of IC dies in the horizontal plane). The term multi-level 3D die stack indicates a die stack having multiple levels such as two or more levels over a base substrate. The term IC die includes any monolithic integrated device that provides electrical, compute, memory, or similar functionality. IC dies include chiplets, chiplet dies, memory dies, processor dies, routing dies, and so on. Herein, the terms chiplet and IC die are used interchangeably. An IC die may be passive such that it only includes electrical routing and passive components such as capacitors, etc., or it may be active such that it includes electrical devices such as transistors, etc. The term base substrate, base wafer, or base die indicates a substrate having active or passive electrical features. In contrast, the term structural substrate, structural wafer, or structural die indicates a substrate absent any active or passive electrical features. For example, a structural substrate may be a monolithic material such as silicon, or other base material that provides structural support and heat removal.

In the context of hybrid bonding of IC dies, faster throughput may be attained during die-to-wafer hybrid bonding (D2W HB) using self-alignment assisted assembly (SA3). In SA3 process flows, a liquid droplet is dispensed on the bonding area on either the top chiplet die or the base wafer to be bonded. A bonder is then used to pick and place the chiplet die onto the base wafer at coarse alignment (e.g., ˜25-50 μm), such that the water droplet is sandwiched in the bonding area between the chiplet and the base wafer. Capillary forces cause the chiplet to self-align to its desired bonding location on the wafer with high positional accuracy (e.g., <200 nm) due to containment features (e.g., SA3 features) designed into the chiplet die and base wafer that confine the droplet to the bonding area with high precision. Such containment features may be characterized as alignment features, SA3 features, or the like. The liquid then evaporates, leaving the chiplet bonded to the base wafer at room temperature due to attractive surface forces (e.g., Van der Waals forces) between the dielectric regions on the chiplet and base wafer. An annealing step is then carried out to form and/or strengthen bonds between the metal pads (e.g., copper pads) dispersed between the dielectric regions, forming electrical interconnects between the chiplet and base wafer. The annealing step may also strengthen the bond between the dielectric regions.

For successful SA3 bonding, the discussed liquid droplet must be effectively confined on the hybrid bonding region. While surface texturing and trench creation are viable techniques to create the contrast, hydrophobic chemical coatings in the non-bonding areas surrounding the hybrid bonding regions offer effective and flexible containment. However, challenges persist in using hydrophobic coatings including damage and/or removal of the coatings during pre-bonding processing. The techniques and structures discussed herein deploy a conformal functional coating or protective coating on sidewalls of the hybrid bonding regions. This functional or protective layer protects the hybrid bonding regions during pre-bond processing. After pre-bond processing and immediately prior to bonding, a hydrophobic coating or layer is selectively applied to the functional or protective layer. This patterned hydrophobic coating or layer effectively confines the liquid droplet during hybrid bonding. Thereby, the hydrophobic coating or layer is not exposed to the harsh chemical processing, high temperatures, and physical distress associated with the pre-bond processing. Such processing decorates the boundary of the hybrid bonding region with a robust material to withstand fab processing, then forms a selective coat of hydrophobic material prior to bonding.

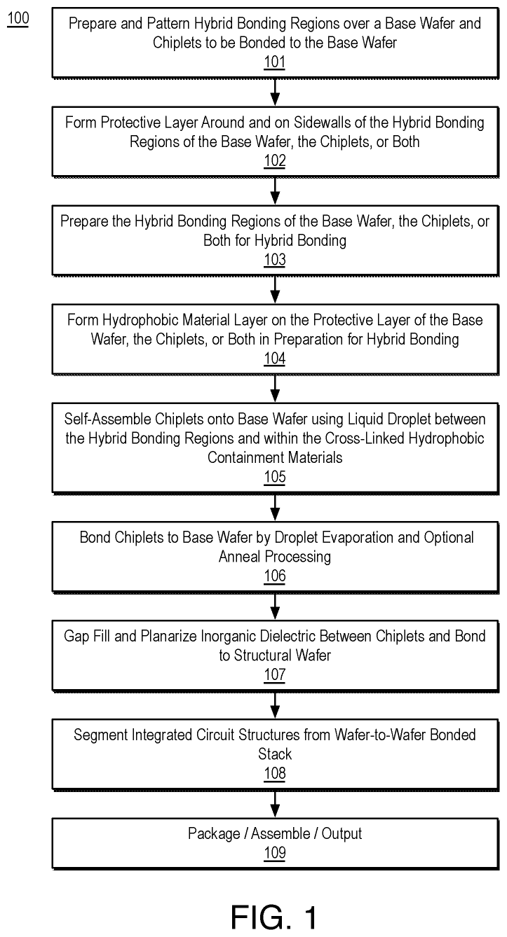

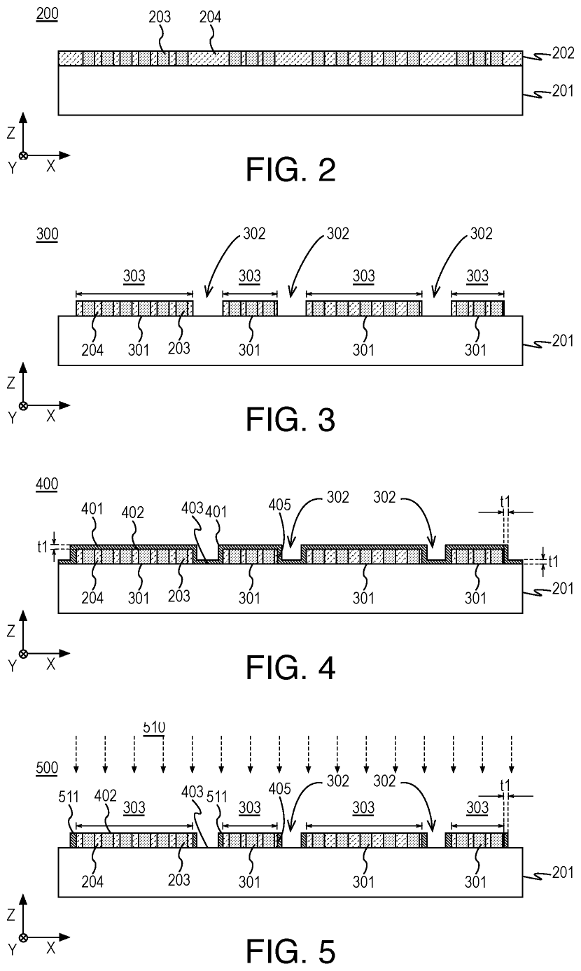

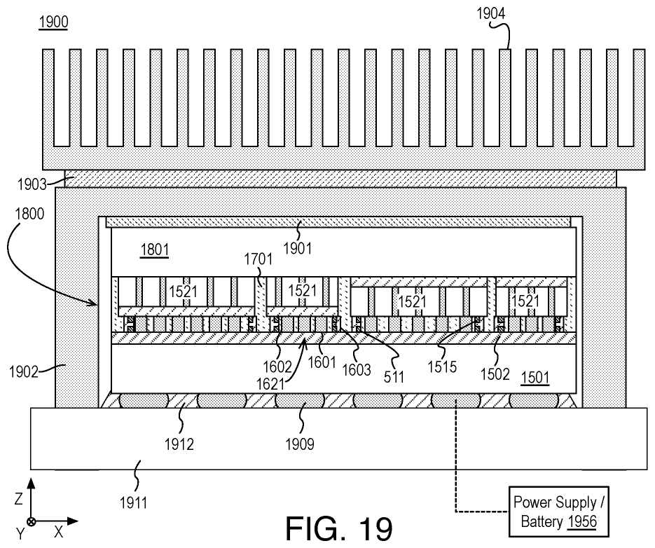

FIG. 1 provides a flow diagram illustrating an example process 100 for fabricating IC structures inclusive of 3D die stacks with hybrid bonding regions within a protective layer and hydrophobic structures on the protective layer, arranged in accordance with at least some implementations of the present disclosure. For example, process 100 may be implemented to fabricate IC structure 1800, as illustrate herein with respect to FIG. 18, or assembly structures including IC structure 1800 such as assembly 1900, as illustrate herein with respect to FIG. 19, or any other structure discussed herein. In the illustrated embodiment, process 100 includes one or more operations as illustrated by operations 101-109. However, embodiments herein may include additional operations, certain operations being omitted, or operations being performed out of the order provided. FIGS. 2-19 illustrate structures and components as the methods of process 100 are practiced.

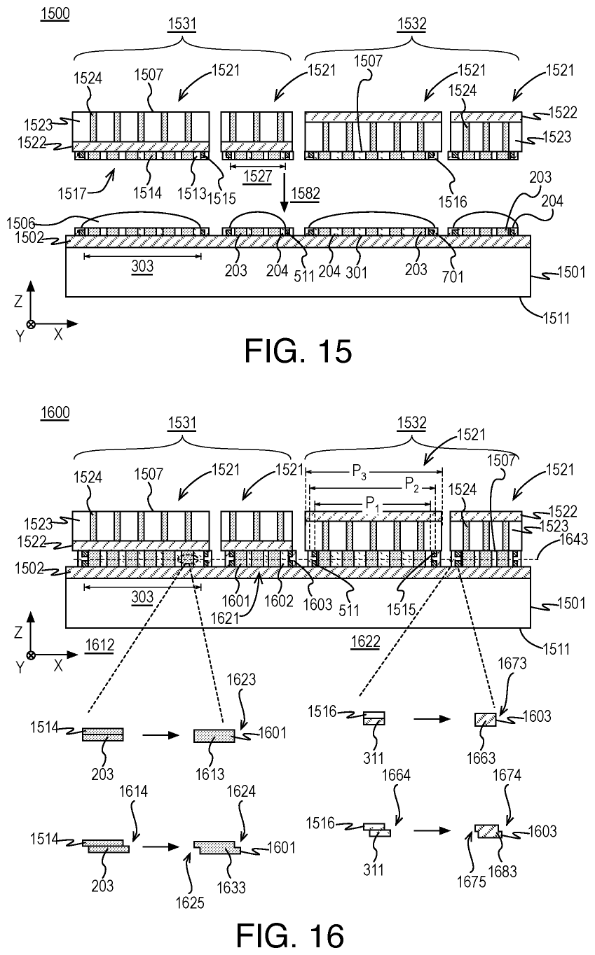

FIGS. 2, 3, 4, 5, 6, 7, 8, 9, 10, 11, 12, 13, and 14A are illustrations of cross-sectional side views of integrated circuit (IC) structures having a hybrid bonding region surrounded by a protective layer and hydrophobic structures being prepared for self-alignment bonding, arranged in accordance with at least some implementations of the present disclosure. FIG. 14B illustrates a top-down view of the IC structure of FIG. 14A showing bonding regions defined by a hydrophobic pattern, arranged in accordance with at least some implementations of the present disclosure. FIGS. 15, 16, 17, and 18 are illustrations of cross-sectional side views of the fabrication of IC structures are illustrations of cross-sectional side views of hybrid bonding of IC dies to a base substrate, arranged in accordance with at least some implementations of the present disclosure. FIG. 19 is an illustration of a cross-sectional side view of an assembly structure similar to the IC structure of FIG. 18 after packaging and deployment of heat removal solutions, arranged in accordance with at least some implementations of the present disclosure.

Process 100 begins at operation 101, where hybrid bonding regions or areas are prepared and/or patterned. The hybrid bonding regions may be formed on or over a base substrate and/or on or over an IC die to be attached to a base substrate.

FIG. 2 is an illustration of a cross-sectional side view of an IC structure 200 being prepared for self-alignment bonding. As shown, IC structure 200 includes a substrate 201 and a hybrid bonding layer 202 formed on substrate 201. Substrate 201 may be a base wafer (as discussed further herein below) or a structural wafer or panel or the like on which IC dies or chiplets are being prepared for hybrid bonding. For example, substrate 201 may be a monolithic material, a crystalline material, or a composite material structural material or substrate 201 may be a base substrate including an interconnect layer, optional device layer, and routing through substrate 201 for connection to an outside package or board.

Hybrid bonding layer 202 includes metal bond pads 203 interspersed in an inorganic dielectric material 204. Inorganic dielectric material 204 may be any suitable material for forming a bond between hybrid bonding layer 202 and another hybrid bonding layer. As used herein, the term inorganic material indicates materials not having carbon as a foundational component or materials not having carbon-hydrogen bonds. In some embodiments, inorganic dielectric material 204 is silicon oxide. In some embodiments, inorganic dielectric material 204 is silicon nitride, silicon oxynitride, silicon carbonitride, or silicon carbide. In some embodiments, the out facing surface of hybrid bonding layer 202 may be planarized to a smooth finish for subsequent bonding. Metal bond pads 203 may be any suitable material for forming a bond between hybrid bonding layer 202 and another hybrid bonding layer and a suitable conductor for the application at hand. In some embodiments, metal bond pads 203 are copper but other metals may be used. In some embodiments, a bulk inorganic dielectric material is formed over substrate 201 and planarized. Metal bond pads 203 are then formed using any suitable technique or techniques such as single or dual damascene techniques.

FIG. 3 illustrates an IC structure 300 similar to IC structure 200 after formation of hydrophilic structures 301 for self-aligned bonding. As discussed, hydrophilic structures 301 include metal bond pads 203 (e.g., copper bond pads) interspersed in inorganic dielectric material 204, which may be silicon oxide, silicon nitride, silicon oxynitride, silicon carbonitride, or silicon carbide. Such materials are hydrophilic such that a liquid (e.g., water) will spread out on hydrophilic structures 301 as the liquid minimizes its surface energy. Patterned hydrophilic structures 301 therefore define hybrid bonding regions 303, which will be bonded to corresponding hybrid bonding regions to build 3D die stacks or structures, as discussed further herein below.

Hydrophilic structures 301 and openings or trenches 302 may be formed from hybrid bonding layer 202 using any suitable technique or techniques such as patterning a resist layer on or over hybrid bonding layer 202, etching the exposed portions of hybrid bonding layer 202 (e.g., via dry etch), and removing the resist layer. In some embodiments, the pattern of hydrophilic structures 301, as defined by hybrid bonding regions 303, matches a desired layout of chiplets or IC dies on substrate 201. In some embodiments, trenches 302 are formed using deep reactive ion etch processing.

Processing continues at operation 102, where the hybrid bonding regions are surrounded by a protective layer or coating that is on sidewalls of the hybrid bonding region but not on the top surface of the hybrid bonding region such that the top of the hybrid bonding region is exposed for further processing. Notably, the protective layer protects the hybrid bonding region and can withstand subsequent processing that is needed to prepare for the hybrid bonding. The protective layer or coating may be formed using any suitable technique or techniques. In some embodiments, the protective layer or coating is first applied as a conformal coating over the hybrid bonding regions and the exposed substrate surfaces. The conformal coating is partially then removed using directional etch techniques to remove the protective layer or coating from horizontal surface (e.g., the top surface of the hybrid bonding region) while the protective layer or coating remains on the sidewall of the hybrid bonding region. The protective layer or coating may then be characterized as a sidewall coating, a spacer, or the like.

FIG. 4 illustrates an IC structure 400 similar to IC structure 300 after formation of a conformal protective material layer 401 on hydrophilic structures 301 and on exposed surfaces of substrate 201. Notably, conformal protective material layer 401 is on top surfaces 402 of hydrophilic structures 301, exposed top surfaces 403 of substrate 201, and sidewalls 405 of hydrophilic structures 301. Conformal protective material layer 401 may be any suitable material to protect at least portions of hydrophilic structures 301 during continued processing. Furthermore, conformal protective material layer 401 may be a material on which a subsequent hydrophobic layer selectively grows. For example, after directional etch, as discussed with respect to FIG. 5, the functional or protective material may serve as a template where hydrophobic coating materials are selectively deposited. Conformal protective material layer 401 may be formed using any suitable technique or techniques such spin-on deposition, chemical vapor deposition (CVD), plasma enhanced chemical vapor deposition (PECVD), physical vapor deposition (PVD), atomic layer deposition (ALD), or the like.

In some embodiments, conformal protective material layer 401 is or includes a metal oxide (e.g., conformal protective material layer 401 includes metal atoms and oxygen). In some embodiments, conformal protective material layer 401 is or includes titanium dioxide (e.g., conformal protective material layer 401 includes titanium and oxygen). In some embodiments, conformal protective material layer 401 is or includes aluminum oxide (e.g., conformal protective material layer 401 includes aluminum and oxygen). In some embodiments, protective material layer 401 is or includes a metal nitride (e.g., conformal protective material layer 401 includes metal atoms and nitrogen). In some embodiments, conformal protective material layer 401 is or includes titanium nitride (e.g., conformal protective material layer 401 includes titanium and nitrogen). In some embodiments, conformal protective material layer 401 is or includes a metal oxynitride (e.g., conformal protective material layer 401 includes metal atoms, oxygen, and nitrogen).

In some embodiments, conformal protective material layer 401 is or includes amorphous carbon (e.g., conformal protective material layer 401 includes carbon). In some embodiments, conformal protective material layer 401 is predominantly amorphous carbon. In some embodiments, conformal protective material layer 401 is substantially amorphous pure carbon. In some embodiments, conformal protective material layer 401 is pure amorphous carbon. As used herein, the term amorphous indicates a solid material having no long-range order.

As shown, conformal protective material layer 401 may be formed or deposited to a thickness t1 such that conformal protective material layer 401 has substantially a thickness t1 orthogonal from any exposed surface such as top surfaces 402 of hydrophilic structures 301, top surfaces 403 of substrate 201, and sidewalls 405 of hydrophilic structures 301. Thickness t1 may be any suitable thickness depending on the material and application. In some embodiments, thickness t1 is not more than 100 nm. In some embodiments, thickness t1 is in the range of 1 to 100 nm. In some embodiments, thickness t1 is in the range of 5 to 100 nm. In some embodiments, thickness t1 is in the range of 5 to 50 nm. In some embodiments, thickness t1 is in the range of 1to 100 nm. In some embodiments, thickness t1 is in the range of 2 to 30 nm. Other thicknesses may be used.

FIG. 5 illustrates an IC structure 500 similar to IC structure 400 after selective removal processing 510 removes portions of conformal protective material layer 401 from top surfaces 402 of hydrophilic structures 301 and top surfaces 403 of substrate 201 to form protective material layer 511. Notably, protective material layer 511 remains on sidewalls 405 of hydrophilic structures 301. For example, protective material layer 511 surrounds inorganic dielectric material 204 and are on sidewalls 405 of inorganic dielectric material 204. Protective material layer 511 may be characterized as a protective layer, functional layer, protective or functional spacer, or simply as a layer.

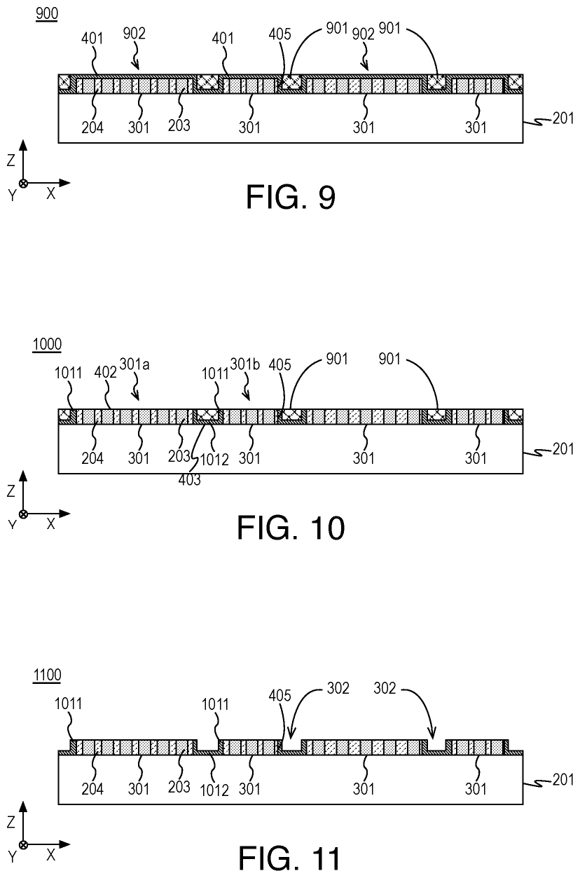

Protective material layer 511 may be formed via any selective removal processing 510 such as directional etch processing, chemical mechanical planarization processing, or similar processing. For example, selective removal processing 510 may be a selective anisotropic dry etch process that removes portions of conformal protective material layer 401 from top surfaces 402 of hydrophilic structures 301 and top surfaces 403 of substrate 201 (e.g., horizontal surfaces) while leaving portions of conformal protective material layer 401 on sidewalls 405 (e.g., vertical surfaces). Notably, such anisotropic etching provides a patterning process to remove the coated film from top surfaces 402 of hydrophilic structures 301 (e.g., the top hybrid bond surface) but leaves the protective material on sidewalls 405 (e.g., inorganic dielectric sidewalls that also define trench sidewalls), where a hydrophobic boundary will subsequently be formed. In some embodiments, selective removal processing 510 includes chemical mechanical planarization processing. In such contexts, portions of protective material layer 401 may remain on top surfaces 403 of substrate 201, as discussed herein with respect to FIGS. 9-11.

Notably, in the removal of portions of protective material layer 511, it is advantageous to consider that, prior to application of protective material layer 511, hybrid bonding regions 303 meets stringent wafer bonding criteria. For example, the surface roughness of hybrid bonding regions 303 may be not more than 1 nm based on a root-mean-square (RMS) roughness metric. Therefore, it is advantageous that the removal of portions of protective material layer 511 from hybrid bonding regions 303 do not compromise the desired surface roughness. For example, the removal process may be tied to the material being removed. In some embodiments, when amorphous carbon is used for protective material layer 511, a gentle directional O₂ or H₂ reactive ion etching (RIE) process may be used to remove protective material layer 511 while not noticeably impacting roughness of hybrid bonding regions 303. In some embodiments, when a metal oxide in some embodiments, deployed for protective material layer 511, the required dry etch chemistries may need to be more aggressive (e.g., inclusive of fluorine or chlorine gases), and may attack the underlying inorganic dielectric material 204 and cause surface roughening. In such contexts, chemical mechanical planarization may be deployed.

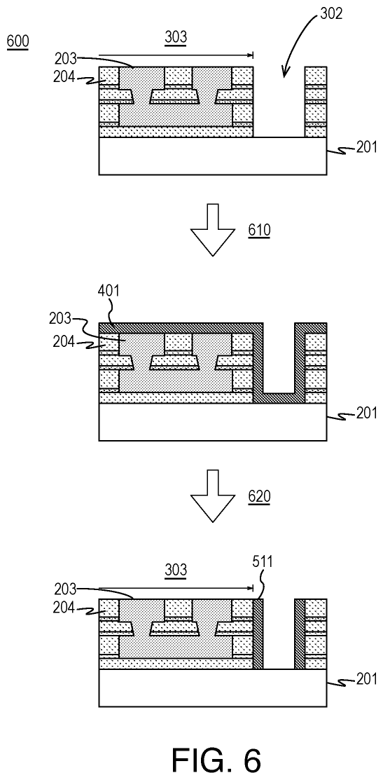

FIG. 6 illustrates exemplary IC structures 600 similar to IC structures 300, 400, 500 during such patterning, protective material conformal deposition, and patterning using directional etch processing. As shown in FIG. 6, a workpiece including substrate 201, inorganic dielectric material 204, and metal bond pads 203 may be patterned as discussed above to form trenches 302, and to define hybrid bonding regions 303. As shown, in some embodiments, metal bond pads 203 are top metallization features of a multi-level metallization stack including, for example, metal lines interconnected by metal vias. Furthermore, inorganic dielectric material 204 may be a top dielectric layer of a multi-level dielectric stack. As shown, trench 302 may be formed in the multi-level dielectric stack using any suitable technique or techniques such as lithography and etch techniques. Subsequently, a conformal deposition process 610 forms conformal protective material layer 401 using any suitable technique or techniques such as spin-on deposition, CVD, PECVD, ALD or PVD. Then, protective material layer 511 is formed using directional or anisotropic etch processing 620. Conformal protective material layer 401 and protective material layer 511 may have any characteristics discussed herein.

Returning to FIG. 1, processing continues at operation 103, where the hybrid bonding regions of the base wafer, the IC chiplets, or both are prepped for hybrid bonding. Such hybrid bonding preparation processing may include any suitable processing inclusive of plasma activation of the hybrid bonding regions, a clean of the hybrid bonding regions, an anneal of the hybrid bonding regions, a test of the hybrid bonding regions, or others. For example, plasma activation may form dangling bonds in the exposed inorganic dielectric material 204 to facilitate bonding. The plasma activation may deploy nitrogen (N₂), oxygen (O₂), hydrogen (H₂), argon (Ar), or other plasma using any suitable process parameters. In some embodiments, the clean of the hybrid bonding regions includes wet etch processing to remove undesired materials and/or to enhance the surfaces of inorganic dielectric material 204, metal bond pads 203, or both, for bonding. In some embodiments, the anneal processing is again to improve the surfaces of inorganic dielectric material 204, metal bond pads 203, or both, for bonding. Alternatively, the anneal processing may be performed in the presence of the hybrid bonding regions but for unrelated reasons. In some embodiments, the test of the hybrid bonding regions may be performed by probing the hybrid bonding regions.

Notably, the protective material layer (i.e., protective material layer 511) protects sidewalls (i.e., sidewalls 405) of the hybrid bonding regions (i.e., hydrophilic structures 301 including inorganic dielectric material 204) during such processing. For example, the protective material layer may advantageously protect the sidewall (and underlying substrate) from plasma damage, etch damage, physical damage, growth of undesired materials, or others during such fabrication processing.

Processing continues at operation 104, where hydrophobic structures (e.g., a hydrophobic material layer) are selectively formed on the protective layer of the base wafer, the chiplets, or both in preparation for hybrid bonding. The hydrophobic structures may be selectively formed on the protective layer using any suitable technique or techniques. In some embodiments, the hydrophobic structures are selectively deposited directly on the protective layer due to an affinity toward the material of the protective layer.

Notably, in process 100, IC dies or chiplets are attached to a base wafer or substrate such that they may be directly attached to the base wafer or substrate or to a layer or level of IC dies or chiplets previously assembled. Such attachment techniques place the IC dies or chiplets onto the base substrate quickly and with gross alignment and then use a liquid droplet between a bonding region of the placed IC die or chiplet and a corresponding bonding region of the base substrate to provide fine alignment using capillary forces. Such self-alignment bonding techniques allow for high throughput as high accuracy, high duration pick and place alignment is not needed. The hydrophobic structures aid in containment of the liquid droplet during such processing.

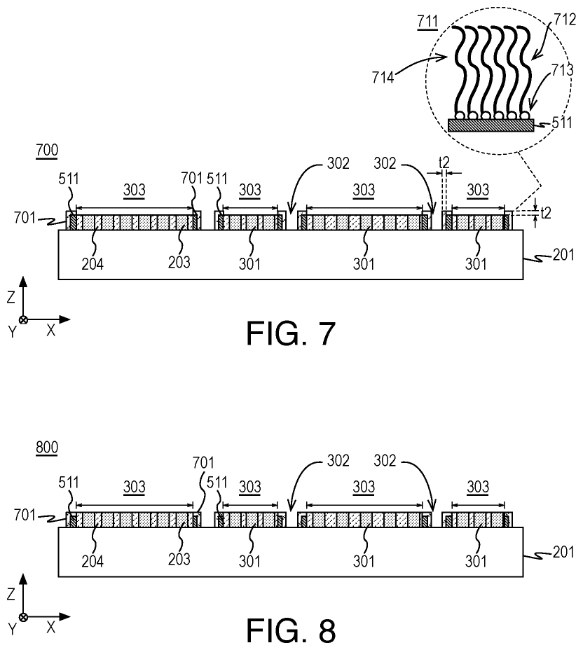

FIG. 7 illustrates an IC structure 700 similar to IC structure 500 after formation of hydrophobic structures 701 on protective material layer 511 and adjacent to hydrophilic structures 301. Hydrophobic structures 701 may be formed on protective material layer 511 using any suitable technique or techniques. In some embodiments, hydrophobic structures 701 are formed by subjecting IC structure 600 (e.g., a workpiece such as a wafer) to a hydrophobic coating process, and hydrophobization occurs selectively on protective material layer 511, which may be characterized as a functional surface.

Hydrophobic structures 701, which may be characterized as hydrophobic boundaries, hydrophobic materials, or the like may include any suitable hydrophobic material (e.g., material that causes a liquid water droplet to have a contact angle of greater than 90°). In some embodiments, hydrophobic structures 701 are chemical coatings or hydrophobic materials that create a hydrophobic boundary with a large contact angle (e.g., >90°) around hybrid bonding regions 303. In some embodiments, the hydrophobic material of hydrophobic structures 701 is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may be used. In some embodiments, the hydrophobic material of hydrophobic structures 701 is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used. In contexts where hydrophobic structures 701 include SAM materials, a SAM 711 of hydrophobic structures 701 may include any suitable hydrophobic SAM having molecules 712 each having a head group 713 to selectively couple to protective material layer 511 and a tail group 714 to provide hydrophobicity.

As shown, hydrophobic structures 701 may be formed or deposited to a thickness t2 such that hydrophobic structures 701 has substantially a thickness t2 orthogonal from any exposed surface of protective material layer 511. Thickness t2 may be any suitable thickness depending on the material and application. In some embodiments, thickness t2 is not more than 10 nm. In some embodiments, thickness t2 is in the range of 1 to 30 nm. In some embodiments, thickness t2 is in the range of 1 to 10 nm. In some embodiments, thickness t2 is in the range of 1 to 5 nm. In some embodiments, hydrophobic structures 701 is a monolayer. Other thicknesses may be used.

As discussed, hydrophobic structures 701 will contain a liquid within hybrid bonding regions 303 while hydrophilic structures 301 allow the liquid to spread out in hybrid bonding regions 303. For example, hydrophilic structures 301 may include inorganic materials such as silicon oxide, silicon nitride, silicon oxynitride, silicon carbonitride, or silicon carbide and copper. Such materials are hydrophilic or treated to become hydrophilic such that a liquid (e.g., water) will spread out on hydrophilic structures 301 as the liquid minimizes its surface energy. Hydrophobic structures such as hydrophobic structures 701, in contrast, will contain the liquid. Hydrophilic materials or surfaces cause a liquid droplet to have a contact angle of less than 90° (e.g., water on silicon oxide has a contact angle of ˜10-20°) while a hydrophobic structure causes a contact angle of greater than 90° in the liquid droplet. As used herein, term hydrophobic structure is inclusive of both topological alterations to a material (e.g., alterations to an otherwise hydrophilic structure) and hydrophobic materials applied to a hydrophilic structure.

In the context of FIG. 7, portions of hydrophobic structures 701 extend above a top surface of hybrid bonding regions 303 (e.g., by thickness t2). In other contexts, prior processing may reduce a size of protective material layer 511 such that application of hydrophobic structures 701 provides a top surface of hybrid bonding regions 303 that is substantially coplanar with a top surface of hydrophobic structures 701.

FIG. 8 illustrates an IC structure 800 similar to IC structure 500 after formation of hydrophobic structures 701 on recessed protective material layer 511 and adjacent to hydrophilic structures 301. Hydrophobic structures 701 may have any characteristics discussed with respect to FIG. 7. In some embodiments, the discussed processing prior to application of hydrophobic structures 701 causes protective material layer 511 to recess vertically (e.g., in the negative z-direction, orthogonal to the x-y plane) or laterally (e.g., in any direction in the x-y plane, orthogonal to the z-direction) or both. Notably, protective material layer 511 may be deposited to achieve the discussed thickness t1 or protective material layer 511 may be deposited at a greater thickness and recessed to the discussed thickness t1. For example, any IC structure or assembly may include protective material layer 511 at any thickness t1 discussed herein.

Discussion now turns to an alternative process for fabricating a protective material layer and hydrophobic structures on the protective material layer. For example, the process illustrated with respect to FIGS. 9-14 may deploy a sacrificial fill technique.

FIG. 9 illustrates an IC structure 900 similar to IC structure 400 after formation of sacrificial material 901 on conformal protective material layer 401 and within trenches 302 (refer to FIG. 4). Sacrificial material 901 may be formed on conformal protective material layer 401 and within trenches 302 using any suitable technique or techniques. In some embodiments, a bulk material layer is formed within trenches 302 and extending over (i.e., in the z-direction) hydrophilic structures 301. The bulk material layer may then be planarized to form sacrificial material 901 within trenches 302 while exposing portions 902 of conformal protective material layer 401.

Sacrificial material 901 may be any suitable material having an etch selectivity with respect to conformal protective material layer 401. In some embodiments, sacrificial material is or includes one of photoresist (PR), organic polymer, amorphous carbon, or spin-on-glass.

FIG. 10 illustrates an IC structure 1000 similar to IC structure 900 after selective removal of exposed portions 902 of conformal protective material layer 401 from top surfaces 402 of hydrophilic structures 301 to form protective material layer 1011. As shown, protective material layer 511 remains on sidewalls 405 of hydrophilic structures 301. Furthermore, as illustrated with respect to hydrophilic structures 301a, 301b, protective material layer 511 surrounds each of hydrophilic structures 301a, 301b, is on sidewalls 405 of inorganic dielectric materials 204 of each of hydrophilic structures 301a, 301b, and a portion 1012 of protective material layer 1011 extends between inorganic dielectric materials 204 of each of hydrophilic structures 301a, 301b. Furthermore, portion 1012 of protective material layer 1011 is on top surface 403 of substrate 201.

Protective material layer 1011 may be formed from conformal protective material layer 401 in the presence of sacrificial material 901 using any suitable technique or techniques. In some embodiments, exposed portions of conformal protective material layer 401 are removed using a selective isotropic etch process such as a wet etch process that removes exposed portions of conformal protective material layer 401 while not substantially impacting sacrificial material 901 and hydrophilic structures 301. Other techniques, such as chemical mechanical planarization processing, may be used. As discussed, it is advantageous to limit the impacts to hydrophilic structures 301 during removal of portions 902 of conformal protective material layer 401. The use of sacrificial material 901 allows a variety of additional processing techniques for low impact removal of portions 902 of conformal protective material layer 401 such as additional wet etch chemistries.

FIG. 11 illustrates an IC structure 1100 similar to IC structure 1000 after selective removal of sacrificial material 901. Sacrificial material 901 may be removed using any suitable technique or techniques. In some embodiments, sacrificial material 901 is removed using a selective isotropic etch process such as a wet etch process that removes sacrificial material 901 while not substantially impacting sacrificial material 901 and hydrophilic structures 301.

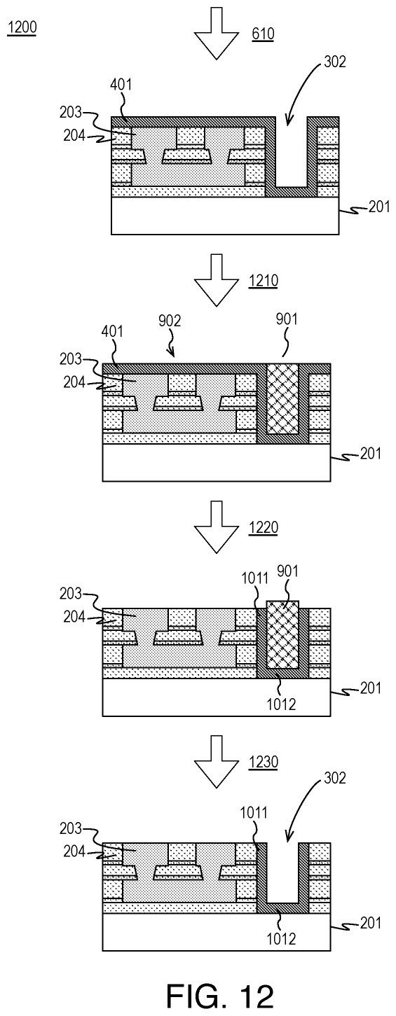

FIG. 12 illustrates exemplary IC structures 1200 similar to IC structures 400, 900, 1000, 1100, during such protective material conformal deposition, sacrificial material deposition, protective material patterning, and sacrificial material removal. As shown in FIG. 12, a workpiece including substrate 201, inorganic dielectric material 204, and metal bond pads 203, after patterning to form trenches 302, may be processed by conformal deposition process 610 to form conformal protective material layer 401. Subsequently, sacrificial material 901 is formed 1210 on conformal protective material layer 401 and within trenches 302 by, for example, bulk layer deposition followed by chemical mechanical planarization. Exposed portions 902 of conformal protective material layer 401 are then removed via, for example, wet etch processing 1220. Subsequently, sacrificial material 901 is removed via, for example, wet etch processing 1230.

With reference to FIG. 1, processing continues at operation 103, where the hybrid bonding regions of the base wafer, the IC chiplets, or both are prepped for hybrid bonding. As discussed, the protective material layer (i.e., protective material layer 1011) protects sidewalls (i.e., sidewalls 405) of the hybrid bonding regions (i.e., hydrophilic structures 301 including inorganic dielectric material 204) during such processing. Processing continues at operation 104, where hydrophobic structures (e.g., a hydrophobic material layer) are selectively formed on the protective layer of the base wafer, the chiplets, or both in preparation for hybrid bonding. The hydrophobic structures may be selectively deposited directly on the protective layer, or the like.

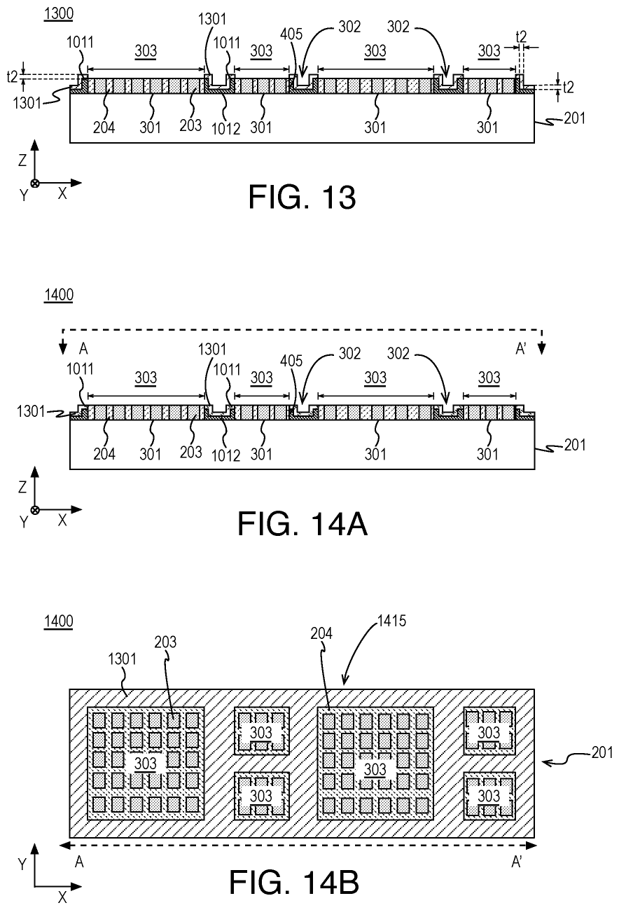

FIG. 13 illustrates an IC structure 1300 similar to IC structure 1100 after formation of hydrophobic structures 1301 on protective material layer 1011 and adjacent to hydrophilic structures 301. Hydrophobic structures 1301 may be formed on protective material layer 1011 using any suitable technique or techniques discussed with respect to hydrophobic structures 701. Furthermore, hydrophobic structures 1301 may have any characteristics discussed with respect to hydrophobic structures 701 For example, hydrophobic structures 1301 may be chemical coatings or hydrophobic materials inclusive of SAM materials, thin polymer films, or other materials that exhibit a large contact angle (e.g., >90°).

In the context of FIG. 13, portions of hydrophobic structures 1301 extend above a top surface of hybrid bonding regions 303 (e.g., by thickness t2). In other contexts, prior processing may reduce a size of protective material layer 1011 such that application of hydrophobic structures 1301 provides a top surface of hybrid bonding regions 303 that is substantially coplanar with a top surface of hydrophobic structures 1301.

FIG. 14A illustrates an IC structure 1400 similar to IC structure 1100 after formation of hydrophobic structures 1301 on recessed protective material layer 1011 and adjacent to hydrophilic structures 301. Hydrophobic structures 1301 may have any characteristics discussed with respect to FIG. 13. For example, processing prior to application of hydrophobic structures 1301 may causes protective material layer 1011 to recess vertically and/or laterally as discussed above.

FIG. 14B illustrates a top-down view of IC structure 1400 showing hybrid bonding regions 303 defined by a hydrophobic pattern 1415 of hydrophobic structures 1301. In the example of FIG. 14B, hydrophobic structures 1301 provide containment within hybrid bonding regions 303. However, hydrophobic structures 701 may provide the same hydrophobic pattern (though not extending between adjacent hybrid bonding regions 303). As shown, hybrid bonding regions 303 may be the same or different sizes and hybrid bonding regions 303 define a chiplet or IC die layout on substrate 201, which underlies hydrophobic pattern 1415 and hybrid bonding regions 303. In some embodiments, an IC die or chiplet is first gross aligned to each of hybrid bonding regions 303. This gross alignment may be performed by pick and place equipment and may be within, for example, 25-50 μm. A liquid droplet (e.g., water droplet) between each of hybrid bonding regions 303 and the corresponding IC die or chiplet then, via capillary forces, provides fine alignment (in a self-aligned manner) of the IC die or chiplet within each of hybrid bonding regions 303. This fine alignment may be to within, for example, 200 nm or less. Alternatively, chiplets may be diced from substrate 201 based on hydrophobic pattern 1415 to provide IC dies or chiplets for bonding to a base substrate.

Returning to FIG. 1, process 100 continues at operation 105, where IC dies or chiplets are self-assembled onto a base wafer using a liquid droplet between hybrid bonding regions and within the hydrophobic containment features prepared as discussed herein. In some embodiments, the water droplet is applied to a hydrophilic hybrid bonding region over a base substrate. In some embodiments, the water droplet is applied to a hydrophilic hybrid bonding region of the IC dies or chiplets. In either event, the IC die hydrophilic hybrid bonding region is placed on or over the hydrophilic bonding region of the base substrate (using gross alignment) and the interplay of the droplet, the hydrophilic bonding regions, and the hydrophobic containment features cause the IC die to self-align with high accuracy.

FIG. 15 is an illustration of a cross-sectional side view of an IC structure 1500 during self-alignment bonding. As shown, IC structure 1500 includes hydrophilic structures 301 on or over a base substrate 1501 and protective material layer 511 and hydrophobic structures 701 adjacent hydrophilic structures 301 and also on or over base substrate 1501. Although illustrated with respect to hydrophilic structures 301, protective material layer 511, and hydrophobic structures 701, any hydrophilic structures, protective material layers, and hydrophobic structures discussed herein may be deployed in the following structures.

As shown, base substrate 1501 includes an active layer 1502. Active layer 1502 (or an active surface) includes a device layer and/or an interconnect layer. For example, a device layer may include transistors, capacitors, or other IC devices. An interconnect layer may be over the device layer and may include metallization levels that interconnect the devices of the device layer and provide routing to outside devices. In some embodiments, base substrate 1501 includes active devices in active layer 1502 and routing from active layer 1502 to a backside surface 1511 of base substrate 1501. In some embodiments, base substrate 1501 includes routing from active layer 1502 to backside surface 1511, and is absent active devices. Base substrate 1501 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. As discussed, a base substrate, base wafer, or base die indicates a substrate having active or passive electrical features. In some embodiments, a multi-level stack of IC dies is formed over base substrate 1501 using die-to-wafer bonding and 3D die complexes are segmented from base substrate 1501 such that each 3D die complex includes a portion of base substrate 1501 and the pertinent attached chiplets over the segmented portion of base substrate 1501.

Furthermore, each of IC dies 1521 includes a substrate 1523, an active layer 1522, and through vias 1524 extending between active layer 1522 and a backside surface 1507 of each of IC dies 1521. Active layer 1522 (or an active surface), similar to active layer 1502, includes a device layer and/or an interconnect layer. For example, the device layer may include transistors, capacitors, or other IC devices. The interconnect layer may be over the device layer and may include metallization levels that interconnect the devices of the device layer and provide routing to outside devices. Substrate 1523 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. Backside surface 1507 is opposite active layer 1522 and may be characterized as a non-active surface.

On or over each of IC dies 1521, hydrophilic structures 1517 (analogous to hydrophilic structures 301), protective material layer 1515 (analogous to protective material layer 511), and hydrophobic structures 1516 (analogous to hydrophobic structures 701) are formed as discussed herein above to define hybrid bonding regions 1527. For example, hydrophilic structures 1517 include metal bond pads 1514 and inorganic dielectric material 1513, which may have any characteristics discussed with respect to metal bond pads 203 and inorganic dielectric material 204. Similarly, protective material layer 1515 may have any characteristics discussed with respect to protective material layers 511, 1011 and hydrophobic structures 1516 may have any characteristics discussed with respect to hydrophobic structures 701, 1301. Although illustrated with exemplary protective material layers and to hydrophobic structures, any such structures discussed herein may be deployed. Hydrophilic structures 1517, protective material layer 1515, and hydrophobic structures 1516 may be formed over a wafer including one or more of IC dies 1521 using the techniques discussed above, and IC dies 1521 may be segmented (e.g., diced) from the wafer for pick and place onto hybrid bonding regions 303, for example.

As shown, liquid droplets 1506 are placed on hybrid bonding regions 303 of hydrophilic structures 301 (or on hybrid bonding regions 1527 of hydrophilic structures 1517). Liquid droplets 1506 may be any suitable liquid such as water of any suitable volume. Hybrid bonding regions 303 and hybrid bonding regions 1527 are brought together using, for example, pick and place of IC dies 1521. As shown, liquid droplets 1506 spread out on hybrid bonding regions 303 (or hybrid bonding regions 1527) and are contained by hydrophobic structures 701 (or hydrophobic structures 1516). IC dies 1521 are grossly and advantageously quickly aligned to hybrid bonding regions 303 and liquid droplets 1506 by pick and place 1582, confined by the self-alignment assisting features discussed herein, quickly fine align each of IC dies 1521 to the corresponding hybrid bonding region 303.

IC dies 1521 may be fabricated and attached such that they are in a face-down configuration 1531 or a face-up configuration 1532. In face-down configuration 1531, active layer 1502 and active layer 1522 are adjacent one another and are directly connected by a hybrid bond therebetween, as discussed further below. Advantageously, through vias 1524 (which may be characterized as through substrate vias or through silicon vias, TSVs), have backside connections on or over backside surface 1507 such that routing from the hybrid bond and active layer 1522 is provided to additional IC dies in the stack (e.g., extending in the z-dimension). In face-up configuration 1532, active layer 1522 is opposite substrate 1523 with respect to active layer 1522. In such contexts, through vias 1524 again have backside connections on or over backside surface 1507 such that routing from the hybrid bond may be provided to active layer 1522, and then to additional IC dies in the stack (e.g., extending in the z-dimension).

Returning to FIG. 1, process 100 continues at operation 106, where the IC dies or chiplets are bonded to the base substrate or wafer by evaporating the liquid droplets and anneal processing. For example, the liquid droplet applied at operation 105 evaporates relatively quickly after alignment and the inorganic materials hold the IC dies or chiplets in place due to, for example, Van der Waals forces. A subsequent anneal operation may be performed to bond the IC dies or chiplets to the bonding regions of the structural wafer by melding metal bond pads and the inorganic materials therebetween.

FIG. 16 is an illustration of a cross-sectional side view of an IC structure 1600 similar to IC structure 1500 after liquid droplets 1506 evaporate and after bonding to form composite metal structures 1601 and a composite dielectric portion 1602 between each of IC dies 1521 and base substrate 1501. Furthermore, hydrophobic structures 701, 1516 may bond to form composite hydrophobic structures 1603. In other contexts, no bonding between hydrophobic structures 701, 1516 occurs. As shown, IC structure 1600 includes base substrate 1501 coupled to active layers 1522 or backside surfaces 1507 of each IC die 1521, depending on whether each IC dies was in face-down configuration 1531 or face-up configuration 1532 during bonding.

As shown, the discussed hybrid bonding forms composite metal structures 1601 and a composite dielectric portion 1602 across a bonding plane 1643. Thereby, a hybrid bond 1621 between IC dies 1521 and base substrate 1501 is formed. Each hybrid bond 1621 includes composite metal structures 1601 and composite dielectric portion 1602. Composite dielectric portion 1602 may be characterized as an inorganic material, an inorganic bond layer, an inorganic bonding material, or the like. As shown, each hybrid bond 1621 is surrounded by composite hydrophobic structures 1603 or by the pertinent hydrophobic structures deployed in forming hybrid bond 1621.

As shown in insert 1612, in some embodiments, adjacent metal pads are annealed to form a composite metal structure 1613 (one of composite metal structures 1601) such that metal structure 1613 has a substantially aligned sidewalls 1623. However, in other embodiments, adjacent metal bond pads 203, 1514 have a misalignment 1614 during anneal and form a composite metal structure 1633 such that metal structure 1633 has a substantially misaligned sidewalls and therefore metal structure 1633 includes a jut 1624 and an overhang 1625. For example, the sidewall of metal structure 1633 may have substantially vertical sidewall portions and a substantially horizontal sidewall portion (e.g., at jut 1624 and overhang 1625).

Similarly, as shown in insert 1622, in some embodiments, adjacent hydrophobic structures 701, 1516 form a composite hydrophobic structure 1663 (e.g., any of composite hydrophobic structures 1603) that has substantially aligned sidewalls 1673. However, in other embodiments, adjacent hydrophobic structures 701, 1516 have a misalignment 1664 during anneal and form a composite hydrophobic structure 1683 (e.g., any of hydrophobic structures 1603) that has a substantially misaligned sidewall 1674 and therefore hydrophobic structure 1683 includes a jut or overhang 1675. For example, the sidewall of hydrophobic structure 1683 may have substantially vertical sidewall portions and a substantially horizontal sidewall portion. In some embodiments, composite hydrophobic structure 1603 extends from a surface of active layer 1502 to active layer 1522 or backside surface 1507 of IC dies 1521.

As discussed, each hybrid bond 1621 is surrounded (entirely or mostly, i.e., >90%) by hydrophobic structures 1603. In the context of FIG. 16, hydrophobic structures 1603 are formed of hydrophobic structures 701, 1516, though the materials of hydrophobic structures 701, 1516 may not combine or meld. As shown in FIG. 16, hydrophobic structure 1603 extends around a perimeter P1 of hybrid bond 1621. As used herein, the term perimeter is used in its ordinary meaning to indicate an outer boundary of hydrophobic structure 1603 in the x-y plane. For perimeters that are not taken in the same plane, such perimeters are projected into the same plane for determination of their dimensions. Furthermore, an outer perimeter P2 of hydrophobic structure 1603 is fully within an outer perimeter P3 of IC die 1521. It is noted that a single continuous hydrophobic structure 1603 may surround hybrid bond 1621 or multiple discontinuous hydrophobic structures 1603 may surround hybrid bond 1621.

Returning to FIG. 1, process 100 continues at operation 107, where a gap fill dielectric is formed between the IC dies and planarized to provide a planar top surface and the structure is attached to a structural substrate such as a structural wafer. In some embodiments, the gap fill dielectric is an inorganic dielectric material such as silicon nitride, silicon oxynitride, silicon carbonitride, or silicon carbide. The gap fill dielectric may be formed using any suitable technique or techniques such as deposition techniques followed by planarization. In some embodiments, the IC structure is bonded to the structural substrate in a wafer-to-wafer bond using an adhesive, an adhesive tape, a dielectric bond, or the like. The structural substrate may be a structural wafer or panel or the like that is absent any active or passive electrical features. For example, the structural substrate may be a monolithic material, a crystalline material, or a composite material. In some embodiments, the structural substrate is monocrystalline silicon such as a silicon wafer. In some embodiments, the structural substrate is or includes germanium, silicon germanium, silicon carbide, or sapphire.

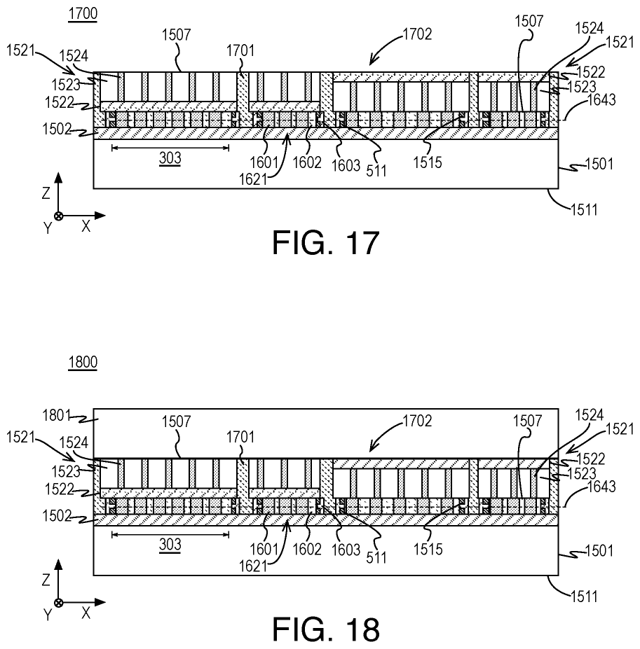

FIG. 17 is an illustration of a cross-sectional side view of IC structure 1700 similar to IC structure 1600 after forming inorganic dielectric 1701 and a substantially planar surface 1702. As shown, inorganic dielectric 1701 may be deposited as a fill material using any suitable technique or techniques such as vapor deposition techniques. The fill material is then planarized using chemical mechanical polishing techniques, to form planar surface 1702. Inorganic dielectric 1701 may be any material suitable dielectric material such as silicon oxide, silicon nitride, silicon oxynitride, silicon carbonitride, silicon carbide, or combinations thereof (e.g., a layer of one of those materials covered by a second layer of another one of those materials). Although inorganic dielectric materials may be advantageous, organic dielectrics may be deployed. As discussed below, planar surface 1702 provides a surface for a subsequent level of IC dies or chiplets in a multi-level 3D die stack.

FIG. 18 is an illustration of a cross-sectional side view of IC structure 1800 similar to IC structure 1700 after bonding IC structure 1700 to a structural substrate 1801. Structural substrate 1801 may be bonded to IC structure 1100 using an adhesive, an adhesive tape, a dielectric bond, or the like (not shown). Structural substrate 1801 may be a structural wafer or panel and is absent any active or passive electrical features. In some embodiments, structural substrate 1801 is or includes monocrystalline silicon, germanium, silicon germanium, silicon carbide, or sapphire. In some embodiments, structural substrate 1801 provides structural support during further processing (e.g., dicing, packaging, assembly, etc.). For example, base substrate 1501 may be thinned while IC structure 1700 is mounted to structural substrate 1801. After such processing and during deployment in an electronic device, structural substrate 1801 may provide a heat conduction path while continuing to provide structural support.

Returning to FIG. 1, process 100 continues at operation 108, where the integrated circuit structure is segmented (or diced) from the wafer-to-wafer bonded stack. For example, IC structure 1800, or any other IC structure discussed herein may be segmented from a wafer using known dicing techniques. Process 100 continues at operation 109, where the resultant device (e.g., IC structure) may be packaged, assembled, and implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 19 illustrates an example microelectronic device assembly 1900 including a 3D die stack having a hybrid bond with a hydrophobic structure and protective layer around an outer perimeter of the hybrid bond, in accordance with some embodiments. For example, FIG. 19 is an illustration of a cross-sectional side view of an assembly structure similar to IC structure 1800 after packaging and deployment of heat removal solutions. As shown, IC structure 1800 may be incorporated into microelectronic device assembly 1900. Although illustrated with respect to the hydrophobic structures and protective layers of FIG. 8, IC structure 1800 and, in turn, microelectronic device assembly 1900, may include any hydrophobic structures and protective layers discussed herein. Furthermore, microelectronic device assembly 1900 may deploy any IC structure discussed herein. Microelectronic device assembly 1900 may include any number of IC structures 1800 mounted to a substrate 1911 via interconnects 1909, which are optionally embedded in a mold or underfill material 1912. Substrate 1911 may be a package substrate, interposer, or board (such as a motherboard). Any number of IC structures 1800 having the same or different hydrophobic structures and protective layers may be attached to substrate 1911.

Microelectronic device assembly 1900 further includes a power supply 1956 coupled to one or more of substrate 1911 (i.e., a board, package substrate, or interposer), IC dies 1521 and/or other components of microelectronic device assembly 1900. Power supply 1956 may include a battery, voltage converter, power supply circuitry, or the like. Microelectronic device assembly 1900 further includes a thermal interface material (TIM) 1901 disposed on a top surface of structural substrate 1801. TIM 1901 may include any suitable thermal interface material and may be characterized as TIM 1. Integrated heat spreader 1902 having a surface on TIM 1901 extends over IC structure 1200 and is mounted to substrate 1911. Microelectronic device assembly 1900 further includes a TIM 1903 disposed on a top surface of integrated beat spreader 1902. TIM 1903 may include any suitable thermal interface material and may be characterized as TIM 2. TIM 1901 and TIM 1903 may be the same materials, or they may be different. A heat sink 1904 (e.g., an exemplary beat dissipation device or thermal solution) is on TIM 1903 and dissipates heat. Microelectronic device assembly 1900 may be used in desktop and server form factors. In other contexts, a heat solution such as a heat pipe or heat spreader may be mounted directly on TIM 1901. Such assemblies may be used in smaller form factor devices. Other heat dissipation devices may be used.

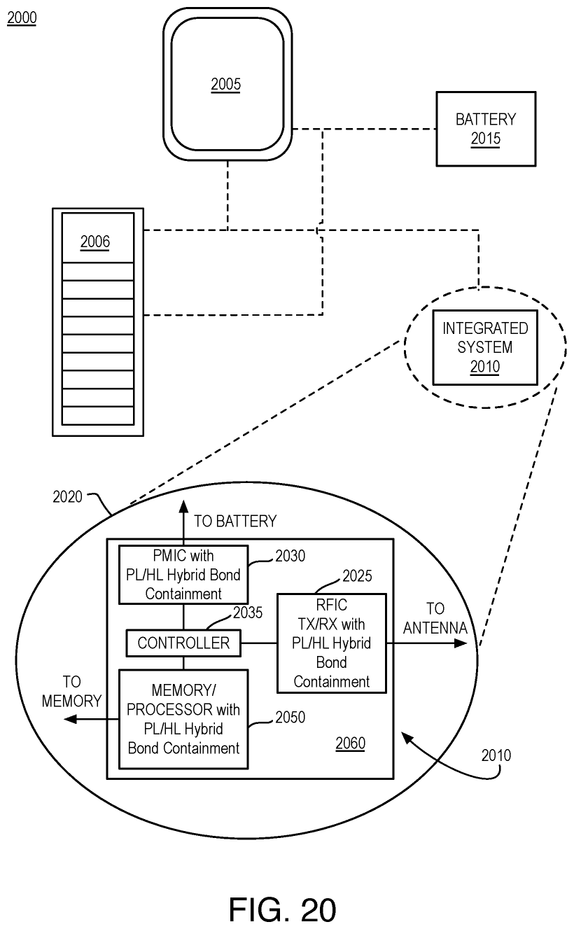

FIG. 20 illustrates an example microelectronic device system 2000 including a 3D die stack having a hybrid bond with a protective layer (PL) and a hydrophobic layer (HL) around an outer perimeter of the hybrid bond, in accordance with some embodiments. The system may be a mobile computing platform 2005 and/or a data server machine 2006, for example. Either may employ a component assembly including an IC structure as described herein. Server machine 2006 may be any commercial server, for example, including any number of high-performance computing platforms disposed within a rack and networked together for electronic data processing, which in the exemplary embodiment includes an integrated circuit (IC) die assembly including a 3D die stack having a hybrid bond with protective layer and a hydrophobic layer around an outer perimeter of the hybrid bond as described elsewhere herein. Mobile computing platform 2005 may be any portable device configured for each of electronic data display, electronic data processing, wireless electronic data transmission, or the like. For example, mobile computing platform 2005 may be any of a tablet, a smart phone, a laptop computer, etc., and may include a display screen (e.g., a capacitive, inductive, resistive, or optical touchscreen), a chip-level or package-level integrated system 2010, and a battery 2015. Although illustrated with respect to mobile computing platform 2005, in other examples, chip-level or package-level integrated system 2010 and a battery 2015 may be implemented in a desktop computing platform, an automotive computing platform, an internet of things platform, or the like. As discussed below, in some examples, the disclosed systems may include a sub-system 2060 such as a system on a chip (SOC) or an integrated system of multiple ICs, which is illustrated with respect to mobile computing platform 2005.

Whether disposed within integrated system 2010 illustrated in expanded view 2020 or as a stand-alone packaged device within data server machine 2006, sub-system 2060 may include memory circuitry and/or processor circuitry 2050 (e.g., RAM, a microprocessor, a multi-core microprocessor, graphics processor, etc.), a power management integrated circuit (PMIC) 2030, a controller 2035, and a radio frequency integrated circuit (RFIC) 2025 (e.g., including a wideband RF transmitter and/or receiver (TX/RX)). As shown, IC dice, such as memory circuitry and/or processor circuitry 2050 may be packaged, assembled, and implemented, such that the package includes a 3D die stack having a hybrid bond with protective layer and a hydrophobic layer around an outer perimeter of the hybrid bond as described herein. In some embodiments, RFIC 2025 includes a digital baseband and an analog front end module further comprising a power amplifier on a transmit path and a low noise amplifier on a receive path). Functionally, PMIC 2030 may perform battery power regulation, DC-to-DC conversion, etc., and so has an input coupled to battery 2015, and an output providing a current supply to other functional modules. As further illustrated in FIG. 20, in the exemplary embodiment, RFIC 2025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2050 may provide memory functionality, high level control, data processing and the like for sub-system 2060. In alternative implementations, each of the SOC modules may be integrated onto separate ICs coupled to a package substrate, interposer, or board.

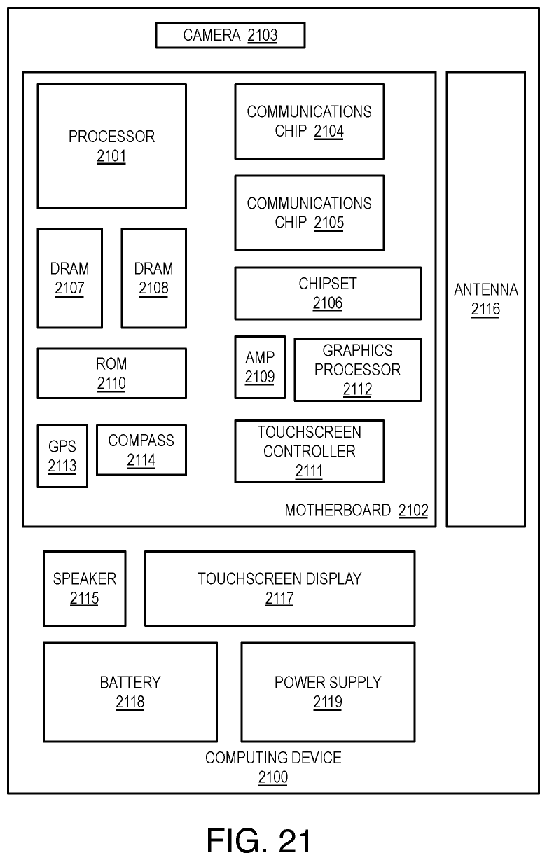

FIG. 21 is a functional block diagram of an electronic computing device 2100, in accordance with some embodiments. For example, device 2100 may, via any suitable component therein, employ a 3D die stack having a hybrid bond with protective layer and a hydrophobic layer around an outer perimeter of the hybrid bond in accordance with any embodiments described elsewhere herein. Device 2100 further includes a motherboard or package substrate 2102 hosting a number of components, such as, but not limited to, a processor 2101 (e.g., an applications processor). Processor 2101 may be physically and/or electrically coupled to package substrate 2102. In some examples, processor 2101 is within a packaged IC assembly that includes a 3D die stack having a hybrid bond with protective layer and a hydrophobic layer around an outer perimeter of the hybrid bond as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 2104, 2105 may also be physically and/or electrically coupled to the package substrate 2102. In further implementations, communication chips 2104, 2105 may be part of processor 2101. Depending on its applications, computing device 2100 may include other components that may or may not be physically and electrically coupled to package substrate 2102. These other components include, but are not limited to, volatile memory (e.g., DRAM 2107, 2108), non-volatile memory (e.g., ROM 2110), flash memory (e.g., NAND or NOR), magnetic memory (MRAM), a graphics processor 2112, a digital signal processor, a crypto processor, a chipset 2106, an antenna 2116, touchscreen display 2117, touchscreen controller 2111, battery 2118, a power supply 2119, audio codec, video codec, power amplifier 2109, global positioning system (GPS) device 2113, compass 2114, accelerometer, gyroscope, speaker 2115, camera 2103, and mass storage device (such as hard disk drive, solid-state drive (SSD), compact disk (CD), digital versatile disk (DVD), and so forth, or the like.

Communication chips 2104, 2105 may enable wireless communications for the transfer of data to and from the computing device 2100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2104, 2105 may implement any of a number of wireless standards or protocols, including, but not limited to, those described elsewhere herein. As discussed, computing device 2100 may include a plurality of communication chips 2104, 2105. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a substrate comprising an interconnect layer, an integrated circuit (IC) die coupled to the interconnect layer of the substrate by composite metal structures embedded within an inorganic dielectric material, a layer surrounding and on a sidewall of the inorganic dielectric material, wherein the layer comprises a metal and one of oxygen or nitrogen, or the layer comprises predominantly carbon, and one or more structures on the layer, wherein the one or more structures comprise a material having an atomic composition of at least ten percent carbon or at least ten percent fluorine.

In one or more second embodiments, further to the first embodiments, the material of the one or more structures comprises a self-assembled monolayer material or a polymer film.

In one or more third embodiments, further to the first or second embodiments, the layer comprises oxygen and the metal comprises one of titanium or aluminum.

In one or more fourth embodiments, further to the first through third embodiments, the layer comprises nitrogen and the metal comprises titanium.

In one or more fifth embodiments, further to the first through fourth embodiments, the layer comprises substantially pure amorphous carbon.

In one or more sixth embodiments, further to the first through fifth embodiments, the layer has a thickness of not more than 100 nm and the one or more structures have a thickness of not more than 10 nm.

In one or more seventh embodiments, further to the first through sixth embodiments, the apparatus further comprises a second IC die coupled to the interconnect layer of the substrate by second composite metal structures embedded within a second inorganic dielectric material, wherein the layer is surrounding and on a sidewall of the second inorganic dielectric material, and wherein the layer extends between the inorganic dielectric material and the second inorganic dielectric material.

In one or more eighth embodiments, further to the first through seventh embodiments, the layer is on the interconnect layer between the inorganic dielectric material and the second inorganic dielectric material.

In one or more ninth embodiments, further to the first through eighth embodiments, the apparatus or a system including the apparatus comprises a power supply coupled to the substrate or the IC die.

In one or more tenth embodiments, an apparatus comprises a substrate comprising an interconnect layer, an integrated circuit (IC) die coupled to the interconnect layer of the substrate by a hybrid bond therebetween, a layer surrounding and on a sidewall of the hybrid bond, wherein the layer comprises a metal and one of oxygen or nitrogen, or the layer comprises predominantly carbon, and a hydrophobic material on the layer and surrounding the hybrid bond.

In one or more eleventh embodiments, further to the tenth embodiments, the hydrophobic material comprises a self-assembled monolayer or a polymer film.

In one or more twelfth embodiments, further to the tenth or eleventh embodiments, the layer comprises oxygen and the metal comprises one of titanium or aluminum, the layer comprises nitrogen and the metal comprises titanium, or the layer comprises substantially pure amorphous carbon.

In one or more thirteenth embodiments, further to the tenth through twelfth embodiments, the apparatus further comprises a second IC die coupled to the interconnect layer of the substrate by a second hybrid bond therebetween, wherein the layer is surrounding and on a sidewall of the second hybrid bond, and wherein the layer extends between the hybrid bond and the second hybrid bond.

In one or more fourteenth embodiments, further to the tenth through thirteenth embodiments, the apparatus or a system including the apparatus comprises a power supply coupled to the substrate or the IC die.

In one or more fifteenth embodiments, a method comprises forming a layer around an outer perimeter of a first hybrid bonding region, wherein the layer comprises a metal and one of oxygen or nitrogen, or the layer comprises predominantly carbon, preparing the first hybrid bonding region for bonding, forming a hydrophobic material on the layer and surrounding the first hybrid bonding region, and evaporating a first liquid droplet between the first hybrid bonding region and a second hybrid bonding region, the first hybrid bonding region of a substrate or an integrated circuit (IC) die and the second hybrid bonding region of the other of the substrate or the IC die, to bond the first hybrid bonding region and the second hybrid bonding regions.

In one or more sixteenth embodiments, further to the fifteenth embodiments, preparing the first hybrid bonding region comprises one of a plasma activation of the first hybrid bonding region, a clean of the first hybrid bonding region, an anneal of the first hybrid bonding region, or a test of the first hybrid bonding region.

In one or more seventeenth embodiments, further to the fifteenth or sixteenth embodiments, forming the layer around the outer perimeter of the first hybrid bonding region comprises forming a conformal layer over and around the first hybrid bonding region, and selectively removing a portion of the conformal layer from over the first hybrid bonding region via a directional etch process.

In one or more eighteenth embodiments, further to the fifteenth through seventeenth embodiments, forming the layer around the outer perimeter of the first hybrid bonding region comprises forming a conformal layer over and around the first hybrid bonding region, wherein the layer surrounds a third hybrid bonding region and a portion of the conformal layer extends between the first hybrid bonding region and the third hybrid bonding region, depositing a sacrificial material on the portion of the conformal layer, removing a portion of the conformal layer from over the first hybrid bonding region, and removing the sacrificial material.

In one or more nineteenth embodiments, further to the fifteenth through eighteenth embodiments, the hydrophobic material comprises a self-assembled monolayer or a polymer film.

In one or more twentieth embodiments, further to the fifteenth through nineteenth embodiments, the layer comprises oxygen and the metal comprises one of titanium or aluminum, the layer comprises nitrogen and the metal comprises titanium, or the layer comprises substantially pure amorphous carbon.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a substrate comprising an interconnect layer;
an integrated circuit (IC) die coupled to the interconnect layer of the substrate by composite metal structures embedded within an inorganic dielectric material;
a layer surrounding and on a sidewall of the inorganic dielectric material, wherein the layer comprises a metal and one of oxygen or nitrogen, or the layer comprises predominantly carbon; and
one or more structures on the layer, wherein the one or more structures comprise a material having an atomic composition of at least ten percent carbon or at least ten percent fluorine.

2. The apparatus of claim 1, wherein the material of the one or more structures comprises a self-assembled monolayer material or a polymer film.

3. The apparatus of claim 1, wherein the layer comprises oxygen and the metal comprises one of titanium or aluminum.

4. The apparatus of claim 1, wherein the layer comprises nitrogen and the metal comprises titanium.

5. The apparatus of claim 1, wherein the layer comprises substantially pure amorphous carbon.

6. The apparatus of claim 1, wherein the layer has a thickness of not more than 100 nm and the one or more structures have a thickness of not more than 10 nm.

7. The apparatus of claim 1, further comprising:
a second IC die coupled to the interconnect layer of the substrate by second composite metal structures embedded within a second inorganic dielectric material, wherein the layer is surrounding and on a sidewall of the second inorganic dielectric material, and wherein the layer extends between the inorganic dielectric material and the second inorganic dielectric material.

8. The apparatus of claim 7, wherein the layer is on the interconnect layer between the inorganic dielectric material and the second inorganic dielectric material.

9. The apparatus of claim 1, further comprising a power supply coupled to the substrate or the IC die.

10. An apparatus, comprising:
a substrate comprising an interconnect layer;
an integrated circuit (IC) die coupled to the interconnect layer of the substrate by a hybrid bond therebetween;
a layer surrounding and on a sidewall of the hybrid bond, wherein the layer comprises a metal and one of oxygen or nitrogen, or the layer comprises predominantly carbon; and
a hydrophobic material on the layer and surrounding the hybrid bond.

11. The apparatus of claim 10, wherein the hydrophobic material comprises a self-assembled monolayer or a polymer film.

12. The apparatus of claim 10, wherein the layer comprises oxygen and the metal comprises one of titanium or aluminum, the layer comprises nitrogen and the metal comprises titanium, or the layer comprises substantially pure amorphous carbon.

13. The apparatus of claim 10, further comprising:
a second IC die coupled to the interconnect layer of the substrate by a second hybrid bond therebetween, wherein the layer is surrounding and on a sidewall of the second hybrid bond, and wherein the layer extends between the hybrid bond and the second hybrid bond.

14. The apparatus of claim 10, further comprising a power supply coupled to the substrate or the IC die.

15. A method, comprising:
forming a layer around an outer perimeter of a first hybrid bonding region, wherein the layer comprises a metal and one of oxygen or nitrogen, or the layer comprises predominantly carbon;
preparing the first hybrid bonding region for bonding;
forming a hydrophobic material on the layer and surrounding the first hybrid bonding region; and
evaporating a first liquid droplet between the first hybrid bonding region and a second hybrid bonding region, the first hybrid bonding region of a substrate or an integrated circuit (IC) die and the second hybrid bonding region of the other of the substrate or the IC die, to bond the first hybrid bonding region and the second hybrid bonding regions.

16. The method of claim 15, wherein preparing the first hybrid bonding region comprises one of a plasma activation of the first hybrid bonding region, a clean of the first hybrid bonding region, an anneal of the first hybrid bonding region, or a test of the first hybrid bonding region.

17. The method of claim 15, wherein forming the layer around the outer perimeter of the first hybrid bonding region comprises:
forming a conformal layer over and around the first hybrid bonding region; and
selectively removing a portion of the conformal layer from over the first hybrid bonding region via a directional etch process.

18. The method of claim 15, wherein forming the layer around the outer perimeter of the first hybrid bonding region comprises:
forming a conformal layer over and around the first hybrid bonding region, wherein the layer surrounds a third hybrid bonding region and a portion of the conformal layer extends between the first hybrid bonding region and the third hybrid bonding region;
depositing a sacrificial material on the portion of the conformal layer;
removing a portion of the conformal layer from over the first hybrid bonding region; and
removing the sacrificial material.

19. The method of claim 15, wherein the hydrophobic material comprises a self-assembled monolayer or a polymer film.

20. The method of claim 15, wherein the layer comprises oxygen and the metal comprises one of titanium or aluminum, the layer comprises nitrogen and the metal comprises titanium, or the layer comprises substantially pure amorphous carbon.
